(19) United States
(12) Patent Application Publication
(10) Pub. No.: US 2022/0243104 A1
(43) Pub. Date: Aug. 4, 2022

(54) SURFACE PROTECTION FILM, METHOD FOR MANUFACTURING SURFACE PROTECTION FILM, AND METHOD FOR MANUFACTURING ORGANIC LIGHT-EMITTING ELECTRONIC DEVICE

(71) Applicant: LG CHEM, LTD., Seoul (KR)

(72) Inventors: Jeong Min Choi, Daejeon (KR); Hyun Cheol Kim, Daejeon (KR); Sojin Kim, Daejeon (KR); Hyungoo Kang, Daejeon (KR); Jae Seung Lym, Daejeon (KR)

(21) Appl. No.: 17/605,531

(22) PCT Filed: Oct. 5, 2020
(86) PCT No.: PCT/KR2020/013473

§ 371 Date: Oct. 21, 2021

(30) Foreign Application Priority Data
Oct. 1, 2019 (KR) 10-2019-0121526
Oct. 1, 2019 (KR) 10-2019-0121535
Oct. 1, 2019 (KR) 10-2019-0121537
Oct. 1, 2019 (KR) 10-2019-0121539

(51) Int. Cl. C09J 151/08; C08J 7/044; C09J 7/29; C09J 7/30; C09J 175/16; C08J 7/04; C09J 133/14; C09J 151/06; H01L 51/56; H01L 27/32

(52) U.S. Cl. CPC C09J 151/08; C08J 2351/06; C09J 7/29; C09J 7/30; C09J 175/16; C08J 7/042; C09J 133/14; C09J 151/06; H01L 51/56; H01L 27/323; C09J 2203/318; C09J 2301/312; C09J 2475/00; C09J 2433/00; C09J 2483/00; C09J 2451/00; C08J 2351/08; C08J 7/044

(57) ABSTRACT

The present application relates to a surface protective film, a method for preparing a surface protective film, and a method for manufacturing an organic light emitting electronic device.

The present application is a National Phase entry pursuant to 35 U.S.C. § 371 of International Application No. PCT/KR2020/013473 filed Oct. 5, 2020, and claims priority to and the benefits of Korean Patent Application No. 10-2019-0121526, filed with the Korean Intellectual Property Office on Oct. 1, 2019, Korean Patent Application No. 10-2019-0121535, filed with the Korean Intellectual Property Office on the same date, Korean Patent Application No. 10-2019-0121537, filed with the Korean Intellectual Property Office on the same date, and Korean Patent Application No. 10-2019-0121539, filed with the Korean Intellectual Property Office on the same date, the entire contents of which are incorporated herein by reference.

### FIELD

The present application relates to a surface protective film, a method for preparing a surface protective film, and a method for manufacturing an organic light emitting electronic device using the surface protective film.

### BACKGROUND

A plastic substrate used as a substrate material of a flexible display has a problem of significantly low gas barrier properties (moisture, oxygen and the like). In view of the above, a barrier film employing various materials and structures has been formed on the substrate in the art in order to mitigate problems of the plastic substrate.

However, as existing barrier films are not used any more recently, development of a surface protective film for a process capable of protecting a thin film encapsulation (TFE) layer during a manufacturing process of a flexible optical device has been required. A surface protective film for a process is a film temporarily protecting a thin film encapsulation layer, and is attached to the thin film encapsulation layer to prevent contamination or damage on the thin film encapsulation layer surface during the process, and is removed when the process is finished.

Properties required for the surface protective film is that, first, an adhesive provided on the surface protective film needs to be well-attached on an adherend surface and needs to prevent damage to the adherend by being removed with low peel strength during the removing step. Second, adherend contamination needs to be prevented by having little adhesive residue after removing the surface protective film.

In order to reduce adhesive strength of an adhesive as a urethane-based adhesive and a plasticizer has been added to control the adhesive strength in the art. However, although low adhesive strength is obtained, adding a plasticizer has caused a problem of surface contamination due to a phenomenon of the plasticizer diffusing to other materials in contact with a product surface and being lost (migration).

### SUMMARY

The present disclosure is directed to providing a surface protective film capable of obtaining low adhesive strength without including a plasticizer, and preventing a surface contamination problem caused by migration of the plasticizer.

In addition, the present disclosure is directed to providing a surface protective film capable of being removed with low peel strength, even when peeling the surface protective film from an adherend at a high rate.

The present disclosure is directed to providing an adhesive layer capable of obtaining low adhesive strength at room temperature (25° C.) without including a plasticizer, and having a small decrease in the adhesive strength caused by an increase in the temperature.

In addition, the present disclosure is directed to providing a surface protective film having a small residue amount when peeling, even when attaching the surface protective film and leaving the film unattended under high temperature and high humidity.

One embodiment of the present disclosure provides a surface protective film including a base layer; and an adhesive layer provided on one surface of the base layer,

wherein the adhesive layer includes a cured material of an adhesive composition including a urethane polymer; an acryl-based polymer; and a curing agent, the acryl-based polymer includes a (meth)acrylate monomer including an alkyl group having 10 or more carbon atoms; a (meth)acrylate monomer including a hydroxyl group; and a (meth)acrylate monomer including silicone as a monomer unit, and

peel strength, when peeling a surface opposite to the base layer-provided surface of the adhesive layer from glass at a peeling rate of 1.8 m/min and a peeling angle of 180°, is greater than or equal to 0.5 gf/in and less than or equal to 5 gf/in.

Another embodiment of the present disclosure provides an adhesive composition including a urethane polymer; an acryl-based polymer; and a curing agent,

wherein the acryl-based polymer includes a (meth)acrylate monomer including an alkyl group having 10 or more carbon atoms; a (meth)acrylate monomer including a hydroxyl group; and a (meth)acrylate monomer including silicone as a monomer unit.

In addition, one embodiment of the present disclosure provides a method for preparing the surface protective film described above using an adhesive composition including a urethane polymer; an acryl-based polymer; and a curing agent,

wherein the acryl-based polymer includes a (meth)acrylate monomer including an alkyl group having 10 or more carbon atoms; a (meth)acrylate monomer including a hydroxyl group; and a (meth)acrylate monomer including silicone as a monomer unit.

Another embodiment of the present specification provides a method for manufacturing an organic light emitting electronic device, the method including attaching the adhesive layer of the surface protective film described above on an encapsulation layer of an organic light emitting device.

A surface protective film of the present disclosure has low adhesive strength to a surface of an adherend at room temperature (25° C.), and therefore, the surface protective film can be removed from the adherend with low peel strength.

The surface protective film of the present disclosure maintains adhesive strength with an adherend even when raising temperature, and delamination of the surface protective film from the adherend at a high temperature can be prevented.

The surface protective film according to one embodiment of the present disclosure has low peel strength even when peeled at a high rate, and therefore, can prevent damage to an adherend surface when peeling at a high rate, and can enhance productivity of a product.

The surface protective film according to one embodiment of the present disclosure has a small adhesive residue amount on an adherend surface even when attached to the adherend and left unattended under a high temperature and high humidity environment, and therefore, damage or contamination on the adherend surface can be prevented after removing the surface protective film.

### BRIEF DESCRIPTION OF THE DRAWINGS

FIG. 1 is a schematic illustration of a surface protective film according to one embodiment of the present disclosure, and a method of use thereof according to one embodiment.

FIG. 2 is a schematic illustration of a surface protective film according to one embodiment of the present disclosure.

FIG. 3 is a schematic illustration of a surface protective film according to another embodiment of the present disclosure.

FIG. 4 is a schematic illustration of a surface protective film according to a further embodiment of the present disclosure.

FIG. 5 is a schematic illustration of a surface protective film attached to an encapsulation layer of an organic light emitting device according to still another embodiment.

### REFERENCE NUMERALS

11A: First Antistatic Layer
11B: Second Antistatic Layer
11C: Third Antistatic Layer
11D: Fourth Antistatic Layer
110: Base Layer
111: Base Film
123: Release Layer
124: Adhesive Layer
130: Protective Layer
131: Protective Film
140: Adherend
510: Organic Light Emitting Device
511: Glass
512: Plastic Substrate
513: Thin Film Transistor
514: Organic Light Emitting Diode
515: Encapsulation layer

### DETAILED DESCRIPTION

Before describing the present disclosure, several terms will be defined first.

In the present specification, a description of a certain part “including” certain constituents means capable of further including other constituents, and does not exclude other constituents unless particularly stated on the contrary.

In the present specification, ‘p to q’ means a range of ‘greater than or equal to p and less than or equal to q’.

In the present specification, a (meth)acrylate includes both an acrylate and a methacrylate.

In the present specification, a polymer including a certain monomer as a monomer unit means the monomer participating in a polymerization reaction and being included in the polymer as a repeating unit. In the present specification, a polymer including a monomer is interpreted in the same manner as the polymer including the monomer as a monomer unit.

In the present specification, it is understood that a ‘polymer’ is used in a broad sense including a copolymer unless specified as a ‘homopolymer’.

In the present specification, a “monomer unit” means that the corresponding compound is polymerized to form bonds in a polymer.

In the present specification, a weight average molecular weight (Mw) and a number average molecular weight (Mn) are polystyrene converted molecular weights employing a monodispersed polystyrene polymer (standard sample) having various degrees of polymerization commercially available for measuring a molecular weight as a standard material, and measured by gel permeation chromatography (GPC). In the present specification, a molecular weight means a weight average molecular weight unless particularly described otherwise.

Embodiments of the present disclosure will be described in detail with reference to accompanying drawings so that those skilled in the art may readily implement the present disclosure. However, the present disclosure may be embodied in various different forms, and is not limited to the following descriptions.

One embodiment of the present disclosure provides a surface protective film including a base layer; and an adhesive layer provided on one surface of the base layer.

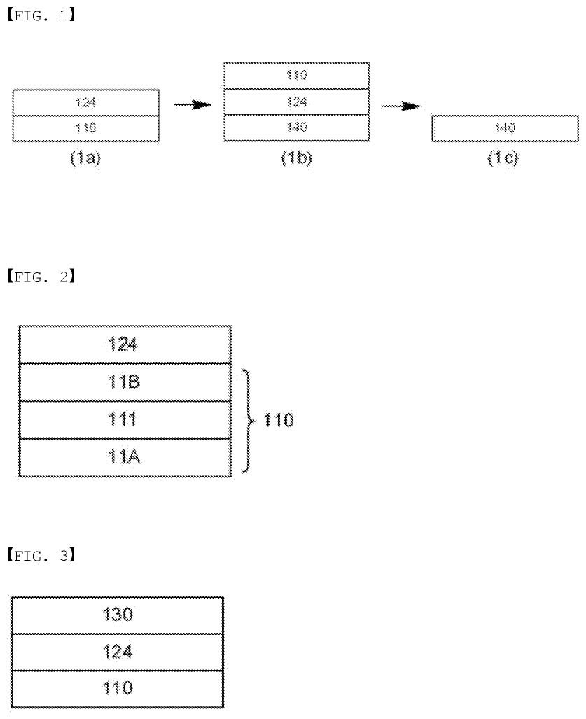

FIG. 1 illustrates a surface protective film (1a) according to one embodiment of the present disclosure, and a form of embodiment thereof. When referring to FIG. 1, the surface protective film according to one embodiment of the present disclosure may be used in a form of attaching an adhesive layer (124) to an adherend (140) to protect a surface of the adherend (lb of FIG. 1).

Herein, the adhesive layer may be formed by curing an adhesive composition including a urethane polymer; an acryl-based polymer; and a curing agent. The urethane polymer goes through a curing reaction with the acryl-based polymer to control ranges of low temperature and high temperature peel strength to ranges to be described later, and may prevent damage on an adherend surface and adhesive residues when peeling the surface protective film from the adherend (1c of FIG. 1).

In addition, the acryl-based polymer includes a (meth)acrylate monomer including an alkyl group having 10 or more carbon atoms; and a (meth)acrylate monomer including silicone as a monomer unit, and low adhesion properties of the adhesive layer may be enhanced by hydrophobic properties of the monomers.

In the present specification, “low temperature low rate peel strength” means peel strength when peeling a surface opposite to the base layer-provided surface of the adhesive layer from glass at a peeling rate of 1.8 m/min and a peeling angle of 180° at 25° C.

In the present specification, “high temperature low rate peel strength” means peel strength when peeling a surface opposite to the base layer-provided surface of the adhesive layer from glass at a peeling rate of 1.8 m/min and a peeling angle of 180° at 50° C.

In the present specification, “low rate peel strength” means the “low temperature low rate peel strength” unless particularly specified otherwise.

In the present specification, “high rate peel strength” means peel strength when peeling a surface opposite to the base layer-provided surface of the adhesive layer from glass at a peeling rate of 30 m/min and a peeling angle of 180°.

In the present specification, “low temperature high rate peel strength” means peel strength when peeling a surface opposite to the base layer-provided surface of the adhesive layer from glass at a peeling rate of 30 m/min and a peeling angle of 180° at 25° C.

In the present specification, the “high rate peel strength” means the “low temperature high rate peel strength” unless particularly specified otherwise.

In one embodiment of the present disclosure, peel strength when peeling a surface opposite to the base layer-provided surface of the adhesive layer from glass at a peeling rate of 1.8 m/min and a peeling angle of 180° is greater than or equal to 0.5 gf/in and less than or equal to 5 gf/in. When the surface protective film has peel strength as above, the surface protective film may be removed from an adherend without damaging the adherend surface. The peel strength herein may be defined as “low temperature peel strength”.

In one embodiment of the present disclosure, the low temperature peel strength is 0.5 gf/in or greater; or 1 gf/in or greater.

In one embodiment, the low temperature peel strength is peel strength obtained when cutting the surface protective film to a width of 25 mm and a length of 150 mm, attaching the adhesive layer of the surface protective film to glass using a kg roller, storing the result for 24 hours under a temperature of 25° C. and relative humidity of 50%, and, using a texture analyzer (manufactured by Stable Micro Systems, UK), peeling the surface protective film from the glass at a peeling rate of 1.8 m/min and a peeling angle of 180° at 25° C.

In one embodiment, the low temperature peel strength is a value measured under a temperature of 25° C. and relative humidity of 50%. In one embodiment of the present disclosure, the adhesive layer may have an adhesive strength retention rate of 45% or greater.

The adhesive strength retention rate of the adhesive layer is (high temperature peel strength)/(low temperature peel strength)×100(%),

the low temperature peel strength is peel strength obtained when attaching the adhesive layer of the surface protective film to glass, storing the result for 24 hours at 25° C., and then peeling the surface protective film from the glass at a peeling rate of 1.8 m/min and a peeling angle of 180° at a temperature of 25° C., and

the high temperature peel strength is peel strength obtained when attaching the adhesive layer of the surface protective film to glass, storing the result for 24 hours at 25° C. and then 1 minute at 50° C., and peeling the surface protective film from the glass at a peeling rate of 1.8 m/min and a peeling angle of 180° at a temperature of 50° C.

The low temperature peel strength is peel strength obtained when attaching the adhesive layer of the surface protective film to glass, storing the result for 24 hours at 25° C., and then peeling the surface protective film from the glass at a peeling rate of 1.8 m/min and a peeling angle of 180° at a temperature of 25° C. In the method of measuring the low temperature peel strength, the surface of the adhesive layer attached to the glass is a surface opposite to the base layer-provided surface of the adhesive layer.

The high temperature peel strength is peel strength obtained when attaching the adhesive layer of the surface protective film to glass, storing the result for 24 hours at 25° C. and then 1 minute at 50° C., and peeling the surface protective film from the glass at a peeling rate of 1.8 m/min and a peeling angle of 180° at a temperature of 50° C. In the method of measuring the high temperature peel strength, the surface of the adhesive layer attached to the glass is a surface opposite to the base layer-provided surface of the adhesive layer.

In one embodiment of the present disclosure, the adhesive layer has an adhesive strength retention rate of 45% or greater; 50% or greater; or 60% or greater.

In one embodiment of the present disclosure, the adhesive layer has an adhesive strength retention rate of 100% or less. In the present specification, the adhesive strength retention rate of 100% means that the low temperature peel strength and the high temperature peel strength are the same.

The adhesive layer according to one embodiment of the present disclosure may maintain adhesive strength even at a high temperature due to an additional curing effect by the acryl-based polymer and a high glass transition temperature (Tg) of the acryl-based polymer present on the surface portion of the adhesive layer. When the adhesive layer has low high temperature adhesive strength, delamination may occur when laminating the surface protective film to a panel and then heating. The adhesive layer according to one embodiment of the present disclosure has a high adhesive strength retention rate even when raising temperature, and delamination of the surface protective film is prevented in a heating process.

In one embodiment of the present disclosure, the adhesive layer has high temperature peel strength of 0.3 gf/in or greater; or 0.5 gf/in or greater.

In one embodiment of the present disclosure, the adhesive layer has high temperature peel strength of 4 gf/in or less; or 3 gf/in or less.

In one embodiment, the high temperature peel strength of the adhesive layer is peel strength obtained when cutting the surface protective film to a width of 25 mm and a length of 150 mm, attaching the adhesive layer of the surface protective film to glass using a 2 kg roller, storing the result for 24 hours under a temperature of 25° C. and relative humidity of 50% and then leaving the surface protective film unattended for 1 minute at 50° C. using a texture analyzer (manufactured by Stable Micro Systems, UK) equipped with a heating chamber, and then peeling the protective film from the glass at a peeling rate of 1.8 m/min and a peeling angle of 180°.

In one embodiment, peel strength when peeling a surface opposite to the base layer-provided surface of the adhesive layer from glass at a peeling rate of 30 m/min and a peeling angle of 180° may be greater than or equal to 1 gf/in and less than or equal to 10 gf/in. When the surface protective film has high rate peel strength as above, an optical member may be stably protected from contamination, and damage on the optical member may be prevented when peeling the surface protective film from the optical member.

In one embodiment of the present disclosure, peel strength when peeling a surface opposite to the base layer-provided surface of the adhesive layer from glass at a peeling rate of 30 m/min and a peeling angle of 180° is 7 gf/in or less; or 3 gf/in or less.

In one embodiment, peel strength when peeling a surface opposite to the base layer-provided surface of the adhesive layer from glass at a peeling rate of 30 m/min and a peeling angle of 180° is peel strength measured when cutting the surface protective film to a width of 25 mm and a length of 150 mm, attaching the adhesive layer of the surface protective film to glass using a 2 kg roller, storing the result for 24 hours at 25° C., and, using a texture analyzer (manufactured by Stable Micro Systems, UK), peeling the protective film from the glass at a peeling rate of 30 m/min and a peeling angle of 180°.

In one embodiment, peel strength when peeling a surface opposite to the base layer-provided surface of the adhesive layer from glass at a peeling rate of 30 m/min and a peeling angle of 180° is a value measured under a temperature of 25° C. and relative humidity of 50%.

In the surface protective film according to one embodiment of the present disclosure, the surface of the adhesive layer has a residual adhesion rate of 100% or less. Having a residual adhesion rate of 100% means the adhesive layer having no residue amount.

The residual adhesion rate means a ratio of the adhesive remaining in the adhesive layer without being left on the adherend, when the adhesive layer is adhered thereto and then peeled off. The ratio may be calculated as a ratio of adhesive strength (B) of the glass surface gone through adhering and peeling of the adhesive layer with respect to initial adhesive strength (A) of the glass surface without adhering and peeling of the adhesive layer of the present disclosure. The adhesive strength (A) and the adhesive strength (B) are compared by measuring adhesive strength when adhering an adhesive (Ref.) prepared in advance to a glass surface, leaving the result unattended and peeling the adhesive.

Adhesive strength (B): the adhesive layer of the disclosure of the present application is adhered to a glass surface, left unattended, and adhesive strength of the glass surface from which the adhesive layer is peeled is measured for the adhesive (Ref.).

Adhesive strength (A): adhesive strength of a glass surface without gone through the adhering, the being left unattended and the peeling is measured for the adhesive (Ref.).

Condition of being left unattended: being left unattended consecutively for 24 hours at 25° C., 10 days at 60° C. and relative humidity of 90%, and 24 hours at 25° C.

Method of measuring adhesive strength: an adhesive (Ref.) is attached to a glass surface, left unattended for 1 hour at 40° C. and 4 hours at 25° C., and the adhesive (Ref.) is peeled to measure adhesive strength. The peeling rate and the peeling angle are the same at 1.8 m/min and 180° when measured.

Adhesive (Ref.): an adhesive having peel strength of 1,800×100 gf/in when, after adhering to a glass surface, peeling at a rate of 1.8 m/min and a peeling angle of 180°, such as 9002D of LG Chem. may be used, however, the adhesive is not limited thereto.

In one embodiment of the present disclosure, the residual adhesion rate of the surface opposite to the base layer-provided surface of the adhesive layer may be obtained by preparing the adhesive (Ref.), measuring the adhesive strength (A) and (B) as follows and then calculating the following formula.

Residual adhesion rate (%)={adhesive strength (B)}/{adhesive strength(A)}×100

Measurement of adhesive strength (B): the protective layer is peeled from the cut surface protective film, and the adhesive layer of the surface protective film is attached to glass. The result is stored for 24 hours at 25° C., and then stored for 10 days in a thermo-hydrostat with a temperature of 60° C. and relative humidity of 90%. After that, the film is taken out and left unattended for 24 hours at 25° C., and then the surface protective film is removed from the glass. The adhesive (Ref.) is attached to the surface protective film-removed glass surface, stored for 1 hour in a 40° C. oven and then left unattended for 4 hours at 25° C., and, using a texture analyzer (manufactured by Stable Micro Systems, UK), peel strength when peeling the adhesive (Ref.) from the glass at a peeling rate of 1.8 m/min and a peeling angle of 180° is measured. This is employed as adhesive strength (B).

Measurement of adhesive strength (A): the adhesive (Ref.) is attached to glass, stored for 1 hour in a 40° C. oven and then left unattended for 4 hours at 25° C., and, using a texture analyzer (manufactured by Stable Micro Systems, UK), peel strength when peeling the adhesive (Ref.) from the glass at a peeling rate of 1.8 m/min and a peeling angle of 180° is evaluated. This is employed as adhesive strength (A).

In one embodiment, the acryl-based polymer has a hydroxyl group value of greater than or equal to 15 mmKOH/g and less than or equal to 50 mmKOH/g. When the acryl-based polymer has a hydroxyl group value of greater than 50 mmKOH/g, a content of the curing agent that needs to be added to the adhesive composition increases, which may reduce wettability of the base layer.

In one embodiment of the present disclosure, the acryl-based polymer is included in 1 parts by weight to 20 parts by weight, with respect to 100 parts by weight of the urethane polymer.

When the content of the acryl-based polymer is less than 1 parts by weight, with respect to 100 parts by weight of the urethane polymer, the effect of reducing adhesive strength of the adhesive layer may be insignificant, and if the content is greater than 20 parts by weight hazing can be caused in the adhesive layer, and therefore, satisfying the above-mentioned range is preferred.

In one embodiment of the present disclosure, the acryl-based polymer is included in 15 parts by weight or less; 12 parts by weight or less; or 10 parts by weight or less, with respect to 100 parts by weight of the urethane polymer.

In one embodiment of the present disclosure, the curing agent is included in 1 parts by weight or greater; 5 parts by weight or greater; or 10 parts by weight or greater, with respect to 100 parts by weight of the urethane polymer.

In one embodiment of the present disclosure, the curing agent is included in 25 parts by weight or less; or 20 parts by weight or less, with respect to 100 parts by weight of the urethane polymer.

When the content of the curing agent is less than 1 parts by weight, with respect to 100 parts by weight of the urethane polymer, a crosslinking reaction between the urethane-based polymer and the acryl-based polymer is not sufficient, which may increase adhesive strength of the adhesive layer at a high temperature. When the content of the curing agent is greater than 25 parts by weight, an isocyanate group remains in the formed adhesive layer causing a problem of increasing adhesive strength of the adhesive layer.

As the urethane polymer in one embodiment of the present disclosure, known urethane polymers may be properly selected and used within a range that does not reduce the effects of the present disclosure.

In one embodiment of the present disclosure, the urethane polymer means a polymer obtained by curing a urethane composition containing a polyol and a multifunctional isocyanate compound.

As the polyol included in the urethane composition, any suitable polyol may be used as long as it is a compound including two or more OH groups. In one embodiment, the polyol may include 2 to 6 OH groups, however, the polyol is not limited thereto.

The polyol included in the urethane composition may be one, two or more types. When using two or more types of the polyol, the mixing ratio may be properly selected.

A number average molecular weight of the polyol included in the urethane composition may be properly selected. In one embodiment, a number average molecular weight of the polyol may be suitably from 100 g/mol to 20,000 g/mol, but is not limited thereto.

In one embodiment, the polyol included in the urethane composition may include a difunctional polyol and a trifunctional polyol. In one embodiment, the amount of the trifunctional polyol in the polyol included in the urethane composition may be from 70% by weight to 100% by weight; 80% by weight to 100% by weight; or 90% by weight to 100% by weight. and The amount of the difunctional polyol may be from 0% by weight to 30% by weight; 0% by weight to 20% by weight; or 0% by weight to 10% by weight. In one embodiment, the polyol including a trifunctional polyol is advantageous in balancing adhesive strength and re-peelability of the adhesive layer.

In one embodiment, when the urethane composition includes a trifunctional polyol, a polyol having a number average molecular weight of 10,000 g/mol to 15,000 g/mol and a polyol having a number average molecular weight of 1,000 g/mol to 5,000 g/mol may be used together as the trifunctional polyol.

In one embodiment, when the urethane composition includes a difunctional polyol, the difunctional polyol may have a number average molecular weight of 100 g/mol to 3,000 g/mol.

The polyol included in the urethane composition preferably does not include an additional functional group having reactivity with the isocyanate group (NCO).

Examples of the polyol included in the urethane composition may include a polyacrylic polyol, a polyether polyol, a polyester polyol, a polycaprolactone polyol, a polycarbonate polyol, a castor oil-based polyol or a combination thereof, but are not limited thereto.

In one embodiment, the degree of dispersion of the molecular weight may be readily controlled when mixing two or more types of the polyol. In one embodiment, the polyol includes the polyether polyol in 50% by weight to 100% by weight; and the polyester polyol in 0% by weight to 50% by weight. In one embodiment, the polyol includes the polyether polyol in 75% by weight to 95% by weight; and the polyester polyol in 5% by weight to 25% by weight.

As the isocyanate compound included in the urethane composition, any suitable multifunctional isocyanate compound commonly used in the art may be selected and used as long as it is a compound usable in a urethanization reaction.

Examples of the multifunctional isocyanate compounds may include a multifunctional aliphatic-based isocyanate, a multifunctional alicyclic-based isocyanate, a multifunctional aromatic-based isocyanate compound, a trimethylol propane adduct obtained by modifying polyisocyanate with a trifunctional isocyanate, a biuret body obtained by reacting polyisocyanate with water, a trimer having an isocyanurate ring and the like, but are not limited thereto.

Examples of the multifunctional aliphatic-based isocyanate compound may include trimethylene diisocyanate, tetramethylene diisocyanate, pentamethylene diisocyanate, hexamethylene diisocyanate, 1,2-propylene diisocyanate, 1,3-butylene diisocyanate, dodecamethylene diisocyanate, 2,4,4-trimethylhexamethylene diisocyanate and the like, but are not limited thereto.

Examples of the multifunctional alicyclic-based isocyanate compound may include isophorone diisocyanate (IPDI), 1,4-cyclohexane diisocyanate (CHDI), 4,4′-dicyclohexylmethane diisocyanate (HMDI), bis(isocyanatomethyl)cyclohexane (HXDI) and the like, but are not limited thereto.

Examples of the multifunctional aromatic-based isocyanate compound may include toluene 2,4-diisocyanate (TDI), toluene 2,6-diisocyanate (TDI), 4,4′-methylene diphenyl diisocyanate (MDI), 2,4′-methylene diphenyl diisocyanate (MDI), polymeric methylene diphenyl diisocyanate (PMDI), p-phenylene diisocyanate (PDI), m-phenylene diisocyanate (PDI), naphthalene 1,5-diisocyanate (NDI), naphthalene 2,4-diisocyanate (NDI), p-xylylene diisocyanate (XDI), 1,3-bis(1-isocyanato-1-methylethyl)benzene (TMXDI) and the like, but are not limited thereto.

In one embodiment of the present disclosure, two or more types of the isocyanate compounds may be mixed into the urethane composition, and herein, type and content of the two or more types of the isocyanate compound may be properly selected. For example, as the isocyanate compound included in the urethane composition, the multifunctional aromatic-based isocyanate compound and the multifunctional aliphatic-based isocyanate compound may be mixed and used together.

In the urethane composition, an OH group of the polyol and an NCO group of the isocyanate compound have an equivalence ratio (NCO group/OH group) of greater than or equal to 0.1 and less than 1. By satisfying the above-mentioned ratio, a urethane polymer formed using the urethane composition may have an OH group present therein.

In one embodiment, the urethane polymer includes a hydroxyl group.

In the urethane composition, a mixing ratio of the polyol and the isocyanate compound may be properly selected.

In one embodiment, the urethane composition may further include other components within a range that does not reduce effects of the present disclosure. For example, the urethane composition may further include a catalyst, a plasticizer, an antioxidant, a leveling agent, a solvent and the like.

As a polymerization method of the urethane polymer, any known proper method may be selected, and in one embodiment, a method such as solution polymerization may be used.

In one embodiment, the urethane polymer may preferably have a weight average molecular weight of 60,000 g/mol to 160,000 g/mol. When the urethane polymer has a weight average molecular weight of less than 60,000 g/mol, the urethane polymer is hard and readily broken, and the urethane polymer having a weight average molecular weight of greater than 160,000 g/mol has a problem of gelling the urethane polymer.

In one embodiment, the urethane polymer has a hydroxyl group value of 3 mgKOH/g to 15 mgKOH/g.

In the present specification, the compound hydroxyl group value may be measured using a titration method. The method of measuring the hydroxyl group value using a titration method is as follows. A compound (1 g) to measure is introduced to an acetylation reagent (25.5 g), and the result is stirred for 2 hours in a 100° C. oil bath. After air cooling the result for 30 minutes, pyridine (10 ml) is introduced thereto. After that, 0.5 N KOH (50 ml, 51 g), a magnetic bar and a phenolphthalein indicator (10 drops) are introduced thereto, and the result is titrated with 0.5 N KOH until the solution turns pink while stirring on a plate.

Acetylation reagent: solution obtained by mixing anhydrous phthalic acid (70 g) and pyridine (500 g)

Phenolphthalein indicator: solution obtained by mixing undiluted phenolphthalein solution (0.5 g), ethanol (250 g) and distilled water (250 g)

The hydroxyl group value may be calculated from the following equation.

Hydroxyl group value=28.05×(A−B)×F/(sample amount)

A: 0.5 N KOH (ml) required for blank

B: 0.5 N KOH (ml) required for the test

F: amount of KOH (ml) when titrating with 0.5 N KOH after introducing magnetic bar and phenolphthalein indicator (10 drops) to 1 N HCL (10 ml)

In one embodiment, the acryl-based polymer includes a (meth)acrylate monomer including an alkyl group having 10 or more carbon atoms; a (meth)acrylate monomer including a hydroxyl group; and a (meth)acrylate monomer including silicone as a monomer unit.

By the acryl-based polymer including a (meth)acrylate monomer including an alkyl group having 10 or more carbon atoms, an adhesive layer peelable from an adherend even with low peel strength may be obtained.

In one embodiment, in the (meth)acrylate monomer including an alkyl group having 10 or more carbon atoms, the number of carbon atoms of the alkyl group is preferably 12 or more.

As long as the alkyl group included in the (meth)acrylate monomer including an alkyl group having 10 or more carbon atoms has 10 or more carbon atoms, effects that the present disclosure aims to provide may be obtained, and the upper limit may be properly selected. In one embodiment, the number of carbon atoms of the alkyl group included in the (meth)acrylate monomer including an alkyl group may be preferably 25 or less, but is not limited thereto.

In one embodiment of the present disclosure, the (meth)acrylate monomer including an alkyl group having 10 or more carbon atoms is an alkyl (meth)acrylate monomer having 10 or more carbon atoms.

In one embodiment, examples of the (meth)acrylate monomer including an alkyl group having 10 or more carbon atoms may include decyl (meth)acrylate, lauryl (meth)acrylate, tridecyl (meth) acrylate, tetradecyl (meth) acrylate, pentadecyl (meth)acrylate, hexadecyl (meth)acrylate, heptadecyl (meth)acrylate, stearyl (meth)acrylate, docosyl (meth)acrylate, behenyl (meth)acrylate and the like, but are not limited thereto.

In one embodiment, the acryl-based polymer may include two or more types of the (meth)acrylate monomer including an alkyl group having 10 or more carbon atoms. In this case, a mixing ratio of the monomers is not particularly limited, and may be properly selected.

In one embodiment of the present disclosure, the (meth)acrylate monomer including an alkyl group having 10 or more carbon atoms is included in 5% by weight or greater, with respect to the total amount of the monomer unit included in the acryl-based polymer. When the content of the (meth)acrylate monomer including an alkyl group having 10 or more carbon atoms is less than 5% by weight, the effect of reducing adhesive strength of the adhesive layer may be reduced.

In one embodiment of the present disclosure, the (meth)acrylate monomer including an alkyl group having 10 or more carbon atoms is included in 20% by weight or less; and preferably 15% by weight or less, with respect to the total amount of the monomer unit included in the acryl-based polymer. When the content of the (meth)acrylate including an alkyl group having 10 or more carbon atoms is greater than 20% by weight, compatibility of the acryl-based polymer and the urethane polymer is low, which may cause haze in the adhesive layer.

In one embodiment of the present disclosure, the acryl-based polymer includes a (meth)acrylate monomer including a hydroxyl group as a monomer unit. The (meth)acrylate monomer including a hydroxyl group allows the urethane polymer and the acryl-based polymer to be crosslinked and thereby prevents adhesive residues on the adherend surface, and may prevent a decrease in adhesive strength of the adhesive layer when a temperature increases.

In one embodiment of the present disclosure, examples of the (meth)acrylate monomer including a hydroxyl group may include 2-hydroxyethyl (meth) acrylate, 2-hydroxypropyl (meth) acrylate, 2-hydroxybutyl (meth) acrylate, 4-hydroxybutyl (meth) acrylate, 6-hydroxyhexyl (meth) acrylate, polyethylene glycol (meth)acrylate, polypropylene glycol (meth)acrylate, polybutylene glycol(meth)acrylate and the like, but are not limited thereto.

In one embodiment of the present disclosure, the (meth)acrylate monomer including a hydroxyl group is an alkyl (meth)acrylate monomer substituted with one or more hydroxyl groups.

In one embodiment of the present disclosure, two or more types of the (meth)acrylate monomer including a hydroxyl group may be mixed and used as the (meth)acrylate monomer including a hydroxyl group. The mixing ratio is not particularly limited, and may be properly selected as necessary.

In one embodiment of the present disclosure, the (meth)acrylate monomer including a hydroxyl group is included in 1% by weight or greater; and preferably 5% by weight or greater, with respect to the total amount of the monomer unit included in the acryl-based polymer.

In one embodiment of the present disclosure, the (meth)acrylate monomer including a hydroxyl group is included in 20% by weight or less; or 15% by weight or less, with respect to the total amount of the monomer unit included in the acryl-based polymer. When the (meth)acrylate including a hydroxyl group is included in greater than 30% by weight, the degree of curing of the acryl-based polymer with the urethane polymer increases causing a problem of the adhesive becoming hard.

In one embodiment of the present disclosure, the (meth)acrylate monomer including silicone is a polyorganosiloxane compound including an acryloyloxy group.

In one embodiment of the present disclosure, the (meth)acrylate monomer including silicone may be a compound represented by the following Chemical Formula 1.

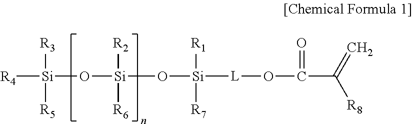

In Chemical Formula 1,

R₁ to R₇ are the same as or different from each other, and each independently an alkyl group,

R₈ is hydrogen or a methyl group,

n is an integer of 0 or greater, and

L is a direct bond; a linear or branched divalent saturated hydrocarbon group; a divalent monocyclic aliphatic saturated hydrocarbon group; a divalent polycyclic saturated hydrocarbon group; a divalent aromatic hydrocarbon group; a divalent group of a ring having cyclic saturated hydrocarbon fused to aromatic hydrocarbon; —O—; —C(═O)—; —C(═O)—O—; or —S—, or a group linking two or more groups of the above-described groups.

In one embodiment of the present disclosure, R₁ to R₇ are the same as or different from each other, and each independently a C₁ to C₁₀ alkyl group.

In one embodiment of the present disclosure, R₁ to R₇ are the same as or different from each other, and each independently a C₁ to C₆ alkyl group.

In one embodiment of the present disclosure, Chemical

Formula 1 is represented by the following Chemical Formula 2.

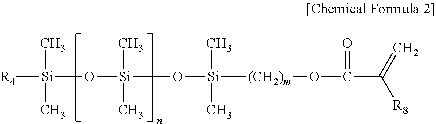

In Chemical Formula 2,

R₄, R₈ and n have the same definitions as in Chemical Formula 1, and

m is an integer of 0 to 10.

In one embodiment of the present disclosure, n is an integer of 1 to 500; 10 to 400; 20 to 350; or 30 to 300.

In one embodiment of the present disclosure, the (meth)acrylate monomer including silicone has a number average molecular weight of 500 g/mol to 10,000 g/mol.

In one embodiment of the present disclosure, the (meth)acrylate monomer including silicone has a number average molecular weight of 10,000 g/mol or less; 9,000 g/mol or less; or 8,000 g/mol or less. When the (meth)acrylate monomer including silicone has a number average molecular weight of greater than 10,000 g/mol, compatibility of the acryl-based polymer and the urethane polymer may be limited.

In one embodiment of the present disclosure, commercially available monomers may be used as the (meth)acrylate monomer including silicone. For example, X-24-8201, X-22-174DX, X-22-2426, X-22-2404, X-22-164A, X-22-164C, FA-4001, FA-4002 and FA-4003 manufactured by Shin-Etsu Chemical Co., Ltd., BY16-152D, BY16-152 and BY16-152C manufactured by Toray Dow Corning Co., Ltd., FM-0711, EA-0721 and FM-0725 manufactured by CHISSO Corporation, KP-541, KP-578, KP-543 and KP-549 manufactured by Shin-Etsu Chemical Co., Ltd., and the like may be used.

In one embodiment of the present disclosure, the (meth)acrylate monomer including silicone is included in 0.1% by weight or greater, with respect to the total amount of the monomer unit included in the acryl-based polymer. When the content of the (meth)acrylate monomer including silicone is less than 0.1% by weight, with respect to the total amount of the monomer unit, the effect of reducing adhesive strength of the adhesive layer may be low.

In one embodiment of the present disclosure, the (meth)acrylate monomer including silicone is included in 5% by weight or less, with respect to the total amount of the monomer unit included in the acryl-based polymer. When the content of the (meth)acrylate including silicone is greater than 5% by weight, with respect to the total amount of the monomer unit included in the acryl-based polymer, compatibility of the acryl-based polymer with the urethane polymer is low, which may cause haze in the adhesive layer.

In one embodiment of the present disclosure, the acryl-based polymer may further include, in addition to the (meth)acrylate monomer including an alkyl group having 10 or more carbon atoms; the (meth)acrylate monomer including a hydroxyl group; and the (meth)acrylate monomer including silicone, other monomer components (other monomers) polymerizable with the (meth)acrylate monomers as a monomer unit in a range that does not reduce effects of the present disclosure.

In one embodiment of the present disclosure, the acryl-based polymer may further include one or more types of (meth)acrylate monomers selected from the group consisting of an alkyl (meth)acrylate having less than 8 carbon atoms, a cycloalkyl (meth)acrylate and an aromatic (meth)acrylate as a monomer unit, but is not limited thereto.

Examples of the alkyl (meth)acrylate having less than 8 carbon atoms may include methyl (meth)acrylate, ethyl (meth) acrylate, n-propyl (meth) acrylate, isopropyl (meth)acrylate, n-butyl (meth)acrylate, t-butyl (meth)acrylate, sec-butyl (meth)acrylate, pentyl (meth)acrylate, 2-ethylbutyl (meth)acrylate and the like, but are not limited thereto.

The aromatic (meth)acrylate means a (meth)acrylate including an aromatic group.

Examples of the aromatic (meth)acrylate may include ortho-biphenyl (meth) acrylate, meta-biphenyl (meth) acrylate, para-biphenyl (meth) acrylate, 2,6-terphenyl (meth) acrylate, ortho-terphenyl (meth)acrylate, meta-terphenyl (meth)acrylate, para-terphenyl (meth) acrylate, 4-(4-methylphenyl)phenyl (meth)acrylate, 4-(2-methylphenyl)phenyl (meth)acrylate, 2-(4-methylphenyl)phenyl (meth) acrylate, 2-(2-methylphenyl)phenyl (meth)acrylate, 4-(4-ethylphenyl)phenyl (meth)acrylate, 4-(2-ethylphenyl)phenyl (meth) acrylate, 2-(4-ethylphenyl)phenyl (meth) acrylate, 2-(2-ethylphenyl)phenyl (meth)acrylate and the like, but are not limited thereto.

Examples of the other (meth)acrylate monomers that may be included in the acryl-based polymer may include cyclohexyl (meth)acrylate, phenyl (meth)acrylate, benzyl (meth)acrylate, 2-phenoxyethyl (meth)acrylate, 2-phenylethyl (meth)acrylate, 3-phenylpropyl (meth)acrylate, 4-phenylbutyl (meth)acrylate, 2,2-methylphenylethyl (meth) acrylate, 2,3-methylphenylethyl (meth) acrylate, 2,4-methylphenylethyl (meth) acrylate, 2-(4-propylphenyl)ethyl (meth) acrylate, 2-(4-(1-methylethyl)phenyl)ethyl (meth)acrylate, 2-(4-methoxyphenyl)ethyl (meth) acrylate, 2-(4-cyclohexylphenyl)ethyl (meth)acrylate, 2-(2-chlorophenyl)ethyl (meth)acrylate, 2-(3-chlorophenyl) ethyl (meth) acrylate, 2-(4-chlorophenyl)ethyl (meth)acrylate, 2-(4-bromophenyl)ethyl (meth)acrylate, 2-(3-phenylphenyl)ethyl (meth) acrylate, 2-(4-benzylphenyl)ethyl (meth)acrylate and the like, but are not limited thereto.

In one embodiment, the acryl-based polymer further includes the alkyl (meth)acrylate monomer having less than 8 carbon atoms in 60% by weight to 90% by weight; or 70% by weight to 80% by weight, with respect to the total amount of the monomer unit included in the acryl-based polymer.

In one embodiment, the acryl-based polymer is a random polymer of the alkyl (meth)acrylate monomer having less than 8 carbon atoms; the (meth)acrylate monomer including an alkyl group having 10 or more carbon atoms; the (meth)acrylate monomer including a hydroxyl group; and the (meth)acrylate monomer including silicone.

In one embodiment, the acryl-based polymer is a random polymer of the alkyl (meth)acrylate monomer having less than 8 carbon atoms; the alkyl (meth)acrylate monomer having 10 or more carbon atoms; the (meth)acrylate monomer including a hydroxyl group; and the (meth)acrylate monomer including silicone.

In the present specification, the alkyl (meth)acrylate means CH₂CR₃₁COOR₃₂ wherein R₃₁ means hydrogen; or a methyl group, and R₃₂ means an alkyl group. In one embodiment, the alkyl (meth)acrylate having 10 or more carbon atoms means the number of carbon atoms of R₃₂ being 10 or greater, and the alkyl (meth)acrylate having less than 8 carbon atoms means the number of carbon atoms of R₃₂ being less than 8.

In one embodiment, the acryl-based polymer is a random polymer of 60% by weight to 90% by weight of the alkyl (meth)acrylate monomer having less than 8 carbon atoms; 5% by weight to 20% by weight of the alkyl (meth)acrylate monomer having 10 or more carbon atoms; 1% by weight to 20% by weight of the (meth)acrylate monomer including a hydroxyl group; and 0.1% by weight to 5% by weight of the (meth)acrylate monomer including silicone.

In one embodiment, the acryl-based polymer is a random polymer of 70% by weight to 80% by weight of the alkyl (meth)acrylate monomer having less than 8 carbon atoms; 5% by weight to 15% by weight of the alkyl (meth)acrylate monomer having 10 or more carbon atoms; 5% by weight to 15% by weight of the (meth)acrylate monomer including a hydroxyl group; and 0.1% by weight to 5% by weight of the (meth)acrylate monomer including silicone.

In one embodiment of the present disclosure, the acryl-based polymer may be polymerized using various generally used polymerization methods such as solution polymerization, peracid polymerization, suspension polymerization, emulsion polymerization and radiation curing polymerization.

In the present specification, the acryl-based polymer may be a random copolymer having a form in which monomers are mixed with each other without order, a block copolymer in which blocks arranged by a certain section are repeated, or an alternating copolymer having a form in which monomers are alternately repeated and polymerized.

In one embodiment, the acryl-based polymer has a hydroxyl group value of greater than or equal to 15 mmKOH/g and less than or equal to 50 mmKOH/g.

In one embodiment of the present disclosure, the acryl-based polymer has a weight average molecular weight of 10,000 g/mol or greater; 15,000 g/mol or greater; or 20,000 g/mol or greater.

In one embodiment of the present disclosure, the acryl-based polymer has a weight average molecular weight of 70,000 g/mol or less; 60,000 g/mol or less; 55,000 g/mol or less; or 50,000 g/mol or less.

When the acryl-based polymer has a molecular weight of less than 10,000 g/mol, the adhesive migrates from the adhesive layer to an adherend surface causing a problem of contamination or the like, and when the acryl-based polymer has a molecular weight of 70,000 g/mol or less, compatibility with the urethane polymer is secured minimizing an occurrence of haze in the adhesive layer, and therefore, satisfying the above-mentioned range is preferred.

In one embodiment of the present disclosure, the curing agent is an isocyanate-based curing agent.

In one embodiment of the present disclosure, the isocyanate-based curing agent may be selected from among diisocyanate compound oligomers, polymers, cyclic monomers, or common aliphatic or aromatic diisocyanate compounds, or commercialized diisocyanate compound oligomers and the like may be purchased and used.

As the isocyanate-based curing agent in one embodiment of the present disclosure, an aromatic cyclic diisocyanate compound having a benzene ring such as 2,4- or 2,6-toluene diisocyanate (TDI), 4,4′-diphenylmethane diisocyanate (MDI), xylene diisocyanate (XDI) or 1,5-naphthalene diisocyanate; an aliphatic noncyclic diisocyanate such as hexamethylene diisocyanate (HDI), propylene diisocyanate, lysine diisocyanate, or 2,2,4- or 2,4,4-trimethylhexamethylene diisocyanate; an aliphatic cyclic diisocyanate compound such as 1,4-cyclohexane diisocyanate, isophorone diisocyanate (IPDI) or 4,4′-dicyclohexylmethane diisocyanate (H12MDI); and a combination thereof may be used, however, the isocyanate-based curing agent is not limited thereto.

In one embodiment of the present disclosure, the isocyanate-based curing agent includes one or more types of the aliphatic cyclic isocyanate compound and the aliphatic noncyclic isocyanate compound.

In one embodiment of the present disclosure, two or more types of the isocyanate-based curing agent may be mixed and used as the adhesive composition, and the ratio may be properly selected.

In one embodiment of the present disclosure, the adhesive composition further includes a solvent. As the solvent, proper known solvents such as ketone-based, acetate-based and toluene-based may be used, however, the solvent is not limited thereto.

In one embodiment of the present disclosure, the adhesive composition further includes a catalyst. The catalyst type or content may be properly selected considering purposes of the present application. The catalyst content (weight) may be from, for example, 10 ppm to 500 ppm with respect to the urethane polymer.

As the catalyst, tin-based catalysts such as dibutyl tin dilaurate (DBTDL), lead-based catalysts, organic and inorganic acid salts, organic metal derivatives, amine-based catalysts, diazabicycloundecene-based catalysts and the like may be used, however, the catalyst is not limited thereto.

In one embodiment of the present disclosure, the adhesive composition may further include a curing retarder. As the curing retarder, any known suitable material may be used, and a content of the curing retarder may be properly selected. In one embodiment, acetylacetone may be used as the curing retarder.

In one embodiment of the present disclosure, the adhesive composition may further include various general additives.

In one embodiment of the present disclosure, the surface protective film includes a base layer; and an adhesive layer provided on one surface of the base layer.

In one embodiment of the present disclosure, the base layer includes a base film; and a first antistatic layer and a second antistatic layer each provided on both surfaces of the base film, and the adhesive layer is provided on a surface of the second antistatic layer opposite to the surface attached to the base film. Such a surface protective film has a form in which a first antistatic layer (11A); a base film (111); a second antistatic layer (11B); and an adhesive layer (124) are consecutively laminated as in FIG. 2.

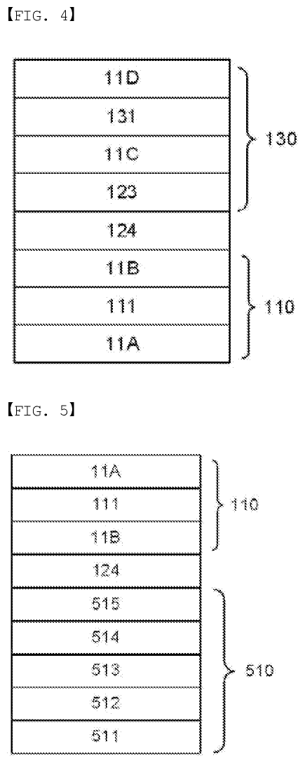

In one embodiment of the present disclosure, the surface protective film further includes a protective layer provided on a surface of the adhesive layer opposite to the surface attached to the base layer. Such a surface protective film has a form in which a base layer (110); an adhesive layer (124); and a protective layer (130) are consecutively laminated as in FIG. 3.

In one embodiment of the present disclosure, the protective layer consecutively includes a release layer; a third antistatic layer; a protective film; and a fourth antistatic layer, and the adhesive layer is provided on a surface opposite to the third antistatic layer-provided surface of the release layer.

In one embodiment, the surface protective film may have a form in which a first antistatic layer (11A); a base film (111); a second antistatic layer (11B); an adhesive layer (124); a release layer (123); a third antistatic layer (11C); a protective film (131); and a fourth antistatic layer (11D) are consecutively laminated as in FIG. 4.

In one embodiment, the surface protective film according to one embodiment of the present disclosure is a surface protective film for protecting a surface of an organic light emitting device during a manufacturing process of an organic light emitting electronic device.

FIG. 1 illustrate a form of use of the surface protective film according to one embodiment of the present disclosure. When referring to FIG. 1, the surface protective film according to one embodiment of the present disclosure may be used in a manner such that a process is progressed by attaching (lb) an adhesive layer (124) of a surface protective film (1a) to an adherend (140), and when the process is completed, the surface protective film is removed (1c) from the adherend (140). In one embodiment, the adherend (140) may be an organic light emitting device.

According to one embodiment of the present disclosure, the adhesive layer is provided on one surface of the second antistatic layer, and thus the amount of accumulated static electricity may be reduced. In addition, since surface resistance of the adhesive layer decreases, generation of static electricity on the adhesive layer surface may be reduced when peeling the protective layer from the surface protective film.

Accordingly, when removing the protective layer from the surface protective film in order to attach the adhesive layer to an adherend surface, or when peeling the surface protective film from an adherend surface, foreign substances that may be attached to the adhesive layer or the adherend by static electricity may be prevented. In addition, decline in the properties of the adherend surface may be prevented by preventing contamination on the adherend surface during the process.

In one embodiment, the surface protective film formed with a base layer and an adhesive layer may be obtained from a surface protective film formed with a base layer, an adhesive layer and a protective layer, removing the protective layer, and may be used by attaching the adhesive layer to a surface of a device to protect.

In the present specification, the adherend means a material to which the adhesive layer may adhere. In one embodiment, the adherend includes an encapsulation layer of an organic light emitting device and a plastic substrate used in the device, but is not limited thereto.

Types of the base film are not particularly limited. Examples of the base film may include a polyethylene terephthalate film, a polytetrafluoroethylene film, a polyethylene film, a polypropylene film, a polybutene film, a polybutadiene film, a vinyl chloride copolymer film, a polyurethane film, an ethylene-vinyl acetate film, an ethylene-propylene copolymer film, an ethylene-ethyl acrylate copolymer film, an ethylene-methyl acrylate copolymer film, a polyimide film or the like, but are not limited thereto. In one embodiment of the present disclosure, the base film may be a polyethylene terephthalate (PET) film.

A thickness of the base film may be properly selected considering purposes of the present application. When the base film thickness is less than 25 μm in bonding the surface protective film to an encapsulation layer of an organic light emitting device, the base film may be readily deformed, and when the base film thickness is greater than 150 μm, bonding defects may occur, and therefore, the base film thickness is preferably from 25 μm to 150 μm. In one embodiment, the base film thickness is 25 μm or greater; or 50 μm or greater. In one embodiment, the base film thickness is 150 μm or less; 125 μm or less; or 100 μm or less.

The base film may have proper adhesion treatment such as corona discharge treatment, ultraviolet irradiation treatment, plasma treatment or sputter etching treatment performed thereon, however, the treatment is not limited thereto.

In one embodiment, the base film may be directly attached to the first and/or the second antistatic layers. In another embodiment, when the base film is surface treated, the first and/or the second antistatic layers may be attached to the surface-treated base film.

The term ‘antistatic layer’ in the present specification means a layer for the purpose of suppressing generation of static electricity.

The first to the fourth antistatic layers may be formed using known methods to achieve target effects. For example, the first to the fourth antistatic layers may be formed on both surfaces of the base film and both surfaces of the protective film using an inline coating method.

In the present disclosure, the first to the fourth antistatic layers may be formed using a proper antistatic composition considering purposes of the present application. For example, the first to the fourth antistatic layers may include one selected from the group consisting of acryl-based resins, urethane-based resins, urethane-acryl-based copolymers, ester-based resins, ether-based resins, amide-based resins, epoxy-based resins and melamine resins, or a mixture thereof, but are not limited thereto.

In one example, the first to the fourth antistatic layers may include a conductive material. The conductive material may include a conductive polymer or carbon nanotubes, but is not limited thereto.

The conductive polymer may include, for example, polyaniline-, polypyrrole-, polythiophene-based, derivatives and copolymers thereof, but is not limited thereto.

The carbon nanotube may have a tube shape formed by rounding a graphite plate shape formed by connecting a hexagonal ring made with 6 carbons to each other. The carbon nanotube has excellent rigidity and electrical conductivity, and when used as the antistatic layer of the surface protective film, hardness of the antistatic layer increases, and an antistatic function may be enhanced.

Thicknesses of the first to the fourth antistatic layers may be properly selected considering purposes of the present application, and the thicknesses of the antistatic layers may be the same as or different from each other.

In one embodiment, thicknesses of the first to the fourth antistatic layers may be each independently 10 nm or greater; or 20 nm or greater. In one embodiment, thicknesses of the first to the fourth antistatic layers may be each independently 400 nm or less; 300 nm or less; or 100 nm or less. When the thicknesses of the first to the fourth antistatic layers each independently greater than or equal to 10 nm and less than or equal to 400 nm, excellent coatability may be obtained on both surfaces of the base film or both surfaces of the protective film.

In one embodiment, surface resistance of the first to the fourth antistatic layers may be properly selected considering purposes of the present application. For example, surface resistance of the first to the fourth antistatic layers may be each independently 10⁴ Ω/sq or greater; 10³ Ω/sq or greater; 10⁶ Ω/sq or greater; 10⁷ Ω/sq or greater; 10⁸ Ω/sq or greater; or 10⁹ Ω/sq or greater. For example, surface resistance of the first to the fourth antistatic layers may be each independently 5×10¹² Ω/sq or less; or 10¹¹ Ω/sq or less. When the first to the fourth antistatic layers have surface resistance in the above-described range, the surface protective film may have an excellent antistatic function.

In one embodiment, the first and the second antistatic layers are each in direct contact with both surfaces of the base film. In one embodiment, the third and the fourth antistatic layers are each in direct contact with both surfaces of the protective film.

In the present disclosure, a thickness of the adhesive layer may be properly selected considering purposes of the present application. In terms of enhancing adhesion and wettability of the adhesive layer for an adherend surface, the adhesive layer thickness is preferably greater than or equal to 10 μm and less than or equal to 200 μm. In one embodiment, the adhesive layer thickness may be 10 μm or greater; 30 μm or greater; or 45 μm or greater. In one embodiment, the adhesive layer thickness may be 200 μm or less; 150 μm or less; 100 μm or less; or 90 μm or less.

The protective film may include, for example, one or more selected from the group consisting of polyethylene terephthalate; polytetrafluoroethylene; polyethylene; polypropylene; polybutene; polybutadiene; a vinyl chloride copolymer; polyurethane; ethylene-vinyl acetate; an ethylene-propylene copolymer; an ethylene-ethyl acrylate copolymer; an ethylene-methyl acrylate copolymer; polyimide; nylon; a styrene-based resin or elastomer; a polyolefin-based resin or elastomer; other elastomers; a polyoxyalkylene-based resin or elastomer; a polyester-based resin or elastomer; a polyvinyl chloride-based resin or elastomer; a polycarbonate-based resin or elastomer; a polyphenylene sulfide-based resin or elastomer; a mixture of hydrocarbon; a polyamide-based resin or elastomer; an acrylate-based resin or elastomer; an epoxy-based resin or elastomer; a silicone-based resin or elastomer; and a liquid crystal polymer, but is not limited thereto.

A thickness of the protective film may be properly selected considering purposes of the present application. In one embodiment, the protective film thickness may be 25 μm or greater. In one embodiment, the protective film thickness may be 150 μm or less; 125 μm or less; or 100 μm or less. When the protective film thickness is less than 25 μm, the protective film may be readily deformed when bonding the adhesive layer-formed surface protective film to an encapsulation layer of an organic light emitting device, and when the protective film thickness is greater than 150 μm, bonding defects may occur.

A material of the release layer may be properly selected according to purposes of the present disclosure. Examples of the release layer material may include a silicone-based release agent, a fluorine-based release agent, a long-chain alkyl-based release agent, a fatty acid amide-based release agent and the like, but are not limited thereto. In one embodiment, a silicone-based release agent may be used as the release layer material.

As the silicone-based release agent, an addition reaction-type silicone polymer may be used, for example.

In one embodiment, the release layer may be formed by coating a release coating solution on a protective layer, and drying the result. As methods of coating and drying the release coating solution, any suitable coating and drying methods may be properly used. Herein, the release coating solution means a composition including the release layer material.

A thickness of the release layer may be properly selected considering purposes of the present application, however, the release layer thickness is preferably from 10 nm to 500 nm in order to prevent defects on the film during the process. In one embodiment, the release layer thickness may be 500 nm or less; 300 nm or less; or 200 nm or less.

In the present specification, unless particularly limited otherwise, ‘glass’ may mean alkali-free glass (Nippon Electric Glass Co., Ltd., OA-21).

One embodiment of the present disclosure provides an adhesive composition including a urethane polymer; an acryl-based polymer; and a curing agent, wherein the acryl-based polymer includes a (meth)acrylate monomer including an alkyl group having 10 or more carbon atoms; a (meth)acrylate monomer including a hydroxyl group; and a (meth)acrylate monomer including silicone as a monomer unit. In the adhesive composition, the descriptions provided above may be applied in the same manner for the urethane polymer; the acryl-based polymer; and the curing agent.

Another embodiment of the present specification provides a method for preparing the surface protective film described above. Accordingly, as for a surface protective film formed using the method for preparing the surface protective film to be described below, the descriptions on the surface protective film provided above may be applied in the same manner.

In one embodiment, the method for preparing the surface protective film includes coating an adhesive composition on one surface of a base layer; and curing the coated adhesive composition, wherein the adhesive composition includes a urethane polymer; an acryl-based polymer; and a curing agent, and the acryl-based polymer includes a (meth)acrylate monomer including an alkyl group having 10 or more carbon atoms; a (meth)acrylate monomer including a hydroxyl group; and a (meth)acrylate monomer including silicone as a monomer unit.

In one embodiment, the forming of an adhesive layer on one surface of a base layer includes coating an adhesive composition on one surface of a base layer; and curing the coated adhesive composition.

In one embodiment, the coating of an adhesive composition on one surface of a base layer is a step of coating the adhesive composition on one surface of a second antistatic layer of the base layer.

In one embodiment, the coating of an adhesive composition on one surface of a base layer is a step of coating the adhesive composition on a surface opposite to the base film-provided surface of the second antistatic layer.

In one example, the method for preparing the surface protective film further includes, between the coating of an adhesive composition on one surface of a base layer and the curing of the coated adhesive composition, forming a protective layer on a surface opposite to the base layer-provided surface of the coated adhesive composition.

In one embodiment, the forming of a protective layer may be a step of forming a protective layer so that a release layer of the protective layer is in contact with the adhesive layer.

In one embodiment, the method for preparing the surface protective film further includes preparing a base layer including a base film, and a first antistatic layer and a second antistatic layer each provided on both surfaces of the base film.

In one embodiment, the method for preparing the surface protective film further includes preparing a protective layer consecutively including a release layer; a third antistatic layer; a protective film; and a fourth antistatic layer.

In another embodiment, the method for preparing the surface protective film may include preparing a base layer including a base film, and a first antistatic layer and a second antistatic layer provided on both surfaces of the base film; preparing a protective layer consecutively including a release layer, a third antistatic layer, a protective film and a fourth antistatic layer; and bonding the base layer and the protective layer by an adhesive layer so that the second antistatic layer and the release layer face each other.

In one embodiment, the method for preparing the surface protective film may further include forming an adhesive layer on one surface of the second antistatic layer of the base layer prior to the bonding of the base layer and the protective layer by the adhesive layer.

In one embodiment, the forming of an adhesive layer on one surface of the second antistatic layer of the base layer includes coating an adhesive composition on one surface of the base layer; and curing the coated adhesive composition, and the adhesive composition includes a urethane polymer; an acryl-based polymer; and a curing agent, and the acryl-based polymer includes a (meth)acrylate monomer including an alkyl group having 10 or more carbon atoms; a (meth)acrylate monomer including a hydroxyl group; and a (meth)acrylate monomer including silicone as a monomer unit.

As a method of coating the adhesive composition, known coating methods such as a reverse coating method, a gravure coating method, a spin coating method, a screen coating method, a fountain coating method, a dipping method and a spray method may be used, however, the method is not limited thereto.

Curing of the coated adhesive composition may be conducted at a proper temperature and for a proper time. In one embodiment, the coated adhesive composition may be cured through aging for 3 days or longer in a 40° C. oven, however, the curing is not limited thereto.

In one embodiment, the surface protective film including a base layer including a base film, and a first antistatic layer and a second antistatic layer provided on both surfaces of the base film; and an adhesive layer provided on a surface of the second antistatic layer opposite to the surface facing the based film may be prepared by peeling the protective layer from the surface protective film including the protective layer described above.

One embodiment of the present disclosure provides a method for manufacturing an organic light emitting electronic device.

In one embodiment of the present disclosure, the method for manufacturing an organic light emitting electronic device includes attaching the adhesive layer of the surface protective film described above on an encapsulation layer of an organic light emitting device.

In one embodiment, when the surface protective film further includes a protective layer, the method for manufacturing an organic light emitting electronic device further includes removing the protective layer from the surface protective film prior to the attaching of the adhesive layer on an encapsulation layer.

In one embodiment of the present disclosure, the organic light emitting device consecutively includes glass, a plastic substrate, a thin film transistor, an organic light emitting diode and an encapsulation layer.

FIG. 5 illustrates a state in which the surface protective film according to one embodiment of the present disclosure is attached on an encapsulation layer during the process of manufacturing an organic light emitting electronic device. When referring to FIG. 5, the surface protective film of FIG. 2 according to one embodiment of the present disclosure is attached on an encapsulation layer (515) of an organic light emitting device (510) consecutively including glass (511), a plastic substrate (512), a thin film transistor (513), an organic light emitting diode (514) and an encapsulation layer (515), so that the adhesive layer (124) and the encapsulation layer (515) face each other.

The encapsulation layer may exhibit excellent moisture barrier properties and optical properties in the organic light emitting electronic device. In addition, the encapsulation layer may be formed as a stable encapsulation layer regardless of a type of the organic light emitting electronic device such as top emission or bottom emission.

In one embodiment, the encapsulation layer may include a single-layered or multilayered inorganic material layer. As a method of forming the encapsulation layer, common methods of forming an encapsulation layer known in the art may be used.

Examples of the single-layered or multilayered inorganic material layer may include aluminum oxide-based, silicon nitride-based, silicon oxynitride-based and the like.

The method for manufacturing an organic light emitting electronic device of the present application may further include peeling the surface protective film from the encapsulation layer; and laminating a touch screen panel and a cover window on the encapsulation layer. The surface protective film has an excellent antistatic function for the encapsulation layer when peeled from the encapsulation layer, which prevents attachment of foreign substances between the encapsulation layer and the touch screen when bonding the touch screen panel on the encapsulation layer, and thereby prevents device defects.

Hereinafter, the present application will be described in more detail through examples that follow the present application and comparative examples that do not follow the present application, however, the scope of the present application is not limited by the examples provided below.

### EXAMPLES

1. Preparation of Urethane Polymer

(1) Preparation of Urethane Polymer U1

To a 3-neck flask filled with nitrogen gas, 80 parts by weight of trifunctional preminol (polyether polyol, S 4013F, ASAHI GLASS CO. LTD., Mn=12,000 g/mol), 5 parts by weight of difunctional polyol (polypropylene glycol, PPG-1000d, KUMHO PETROCHEMICAL, Mn=1,000 g/mol), 15 parts by weight trifunctional MPD/TMPT-based polyol (mixture of MPD (3-methyl-1,5-pentanediol) and TMPT (trimethylol propane adipate), Polyol F-3010, Kuraray Co., Ltd., Mn=3,000 g/mol) and ethyl acetate were introduced, and stirred for 15 minutes at a high rate under a catalyst (DBTDL). Then, the mixture was heated while 18 parts by weight of a multifunctional alicyclic isocyanate compound (MHG-80B, ASAHI KASEI Corporation) was slowly added dropwise thereto with respect to 100 parts by weight of the preminol, the polyol and the MPD/TMPT-based polyol, and the result was kept for 3 hours at 90±5° C. and reacted until the isocyanate (NCO) peak disappeared to prepare Urethane Polymer U1 having a weight average molecular weight of 110,000 g/mol.

(2) Preparation of Urethane Polymer U2

Urethane Polymer U2 was prepared in the same manner as Urethane Polymer U1 except that the weight average molecular weight was changed to 80,000 g/mol.

2. Preparation of Acryl-Based Polymer

(1) Preparation of Acryl-Based Polymer D1

To a 1 L reactor having nitrogen gas refluxed therein and equipped with a cooling device so as to readily control a temperature, a monomer mixture formed with 79.5 parts by weight of butyl methacrylate (BMA), 10 parts by weight of stearyl methacrylate (STMA), 0.5 parts by weight of (meth)acrylate including silicone {FM-0721 (CHISSO Corporation, Mn=5,000 g/mol)} and 10 parts by weight of hydroxybutyl acrylate was introduced, and ethyl acetate was introduced thereto as a solvent. Then, the reactor was purged with nitrogen gas for approximately 1 hour to remove oxygen, and the reactor temperature was maintained at 62° C. After homogenizing the mixture, 400 ppm of azobisisobutylnitrile (AIBN) as a reaction initiator and 400 ppm of n-dodecyl mercaptan (n-DDM) as a chain transfer agent were introduced thereto, and the mixture was reacted. After the reaction, the result was diluted with toluene to prepare Acryl-based Polymer D1 having a weight average molecular weight of 28,000 g/mol.

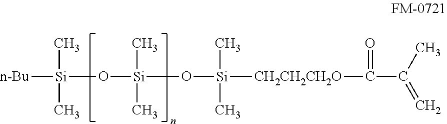

(2) Preparation of Acryl-Based Polymer D2

To a 1 L reactor having nitrogen gas refluxed therein and equipped with a cooling device so as to readily control a temperature, a monomer mixture formed with 79.5 parts by weight of butyl methacrylate (BMA), 5 parts by weight of stearyl methacrylate (STMA), 0.5 parts by weight of FM-0721 (CHISSO Corporation, Mn=5,000 g/mol) and 15 parts by weight of hydroxyhexyl acrylate (HHA) was introduced, and ethyl acetate was introduced thereto as a solvent. Then, the reactor was purged with nitrogen gas for approximately 1 hour to remove oxygen, and the reactor temperature was maintained at 62° C. After homogenizing the mixture, 400 ppm of azobisisobutylnitrile (AIBN) as a reaction initiator and 400 ppm of n-dodecyl mercaptan (n-DDM) as a chain transfer agent were introduced thereto, and the mixture was reacted. After the reaction, the result was diluted with toluene to prepare Acryl-based Polymer D2 having a weight average molecular weight of 28,000 g/mol.

(3) Preparation of Acryl-Based Polymer D3

Acryl-based Polymer D3 was prepared in the same manner as in Preparation of Acryl-based Polymer D2 except that the weight ratio of BMA, STMA, FM-0721 and HHA was employed as 82.5:5:0.5:12 instead of 79.5:5:0.5:15.

(4) Preparation of Acryl-Based Polymer D4

Acryl-based Polymer D4 was prepared in the same manner as in Preparation of Acryl-based Polymer D2 except that the weight ratio of BMA, STMA, FM-0721 and HHA was employed as 84.5:5:0.5:10 instead of 79.5:5:0.5:15.

(5) Preparation of Acryl-Based Polymer D5

Acryl-based Polymer D5 was prepared in the same manner as in Preparation of Acryl-based Polymer D2 except that the weight ratio of BMA, STMA, FM-0721 and HHA was employed as 86.5:5:0.5:8 instead of 79.5:5:0.5:15.

(6) Preparation of Acryl-Based Polymer D6

Acryl-based Polymer D6 was prepared in the same manner as in Preparation of Acryl-based Polymer D2 except that the weight ratio of BMA, STMA, FM-0721 and HHA was employed as 88.5:5:0.5:5 instead of 79.5:5:0.5:15.

(7) Preparation of Acryl-Based Polymer D7

To a 1 L reactor having nitrogen gas refluxed therein and equipped with a cooling device so as to readily control a temperature, a monomer mixture formed with 84 parts by weight of butyl methacrylate (BMA), 5 parts by weight of stearyl methacrylate (STMA), 1 parts by weight of Si-acrylate (X-24-8201 (one end methacrylate substituted dimethylpolysiloxane), Shin-Etsu Chemical Co., Ltd., Mn=2,100 g/mol) and 10 parts by weight of hydroxybutyl acrylate was introduced, and ethyl acetate was introduced thereto as a solvent. Then, the reactor was purged with nitrogen gas for approximately 1 hour to remove oxygen, and the reactor temperature was maintained at 62° C. After homogenizing the mixture, 400 ppm of azobisisobutylnitrile (AIBN) as a reaction initiator and 400 ppm of n-dodecyl mercaptan (n-DDM) as a chain transfer agent were introduced thereto, and the mixture was reacted. After the reaction, the result was diluted with toluene to prepare Acryl-based Polymer D7 having a weight average molecular weight of 15,000 g/mol.

(8) Preparation of Acryl-Based Polymer D8

Acryl-based Polymer D8 was prepared in the same manner as in Preparation of Acryl-based Polymer D7 except that the weight average molecular weight was changed to 27,000 g/mol.

(9) Preparation of Acryl-Based Polymer D9

Acryl-based Polymer D9 was prepared in the same manner as in Preparation of Acryl-based Polymer D7 except that FM-0721 (CHISSO Corporation, Mn=5,000 g/mol) was used instead of X-24-8201 as the Si-acrylate.

(10) Preparation of Acryl-Based Polymer D10

Acryl-based Polymer D10 having a weight average molecular weight of 35,000 g/mol was prepared in the same manner as in Preparation of Acryl-based Polymer D7 except that FM-0721 (CHISSO Corporation, Mn=5,000 g/mol) was used instead of X-24-8201 as the Si-acrylate.

(11) Preparation of Acryl-Based Polymer D11

Acryl-based Polymer D11 having a weight average molecular weight of 39,000 g/mol was prepared in the same manner as in Preparation of Acryl-based Polymer D7 except that FM-0721 (CHISSO Corporation, Mn=5,000 g/mol) was used instead of X-24-8201 as the Si-acrylate.

(12) Preparation of Acryl-Based Polymer D12

To a 1 L reactor having nitrogen gas refluxed therein and equipped with a cooling device so as to readily control a temperature, a monomer mixture formed with 84.3 parts by weight of butyl methacrylate (BMA), 5 parts by weight of decyl methacrylate, 0.7 parts by weight of FM-0711 (CHISSO Corporation, Mn=1,000 g/mol) and 10 parts by weight of hydroxyethyl acrylate (HEA) was introduced, and ethyl acetate was introduced thereto as a solvent. Then, the reactor was purged with nitrogen gas for approximately 1 hour to remove oxygen, and the reactor temperature was maintained at 62° C. After homogenizing the mixture, 400 ppm of azobisisobutylnitrile (AIBN) as a reaction initiator and 400 ppm of n-dodecyl mercaptan (n-DDM) as a chain transfer agent were introduced thereto, and the mixture was reacted. After the reaction, the result was diluted with toluene to prepare Acryl-based Polymer D12 having a weight average molecular weight of 28,000 g/mol.

(13) Preparation of Acryl-Based Polymer D13

Acryl-based Polymer D13 was prepared in the same manner as in Preparation of Acryl-based Polymer D12 except that dodecyl methacrylate was used instead of decyl methacrylate.

(14) Preparation of Acryl-Based Polymer D14

Acryl-based Polymer D14 was prepared in the same manner as in Preparation of Acryl-based Polymer D12 except that tetradecyl methacrylate was used instead of decyl methacrylate.

(15) Preparation of Acryl-Based Polymer D15

Acryl-based Polymer D15 was prepared in the same manner as in Preparation of Acryl-based Polymer D12 except that stearyl methacrylate was used instead of decyl methacrylate.

(16) Preparation of Acryl-Based Polymer D16

Acryl-based Polymer D16 was prepared in the same manner as in Preparation of Acryl-based Polymer D12 except that behenyl methacrylate was used instead of decyl methacrylate.

3. Preparation of Adhesive Composition

(1) Preparation of Adhesive Composition 1

100 Parts by weight of the prepared Urethane Polymer U1, and, with respect to 100 parts by weight of Urethane Polymer U1, 15 parts by weight of an HDI trimer-based curing agent (TKA-100, ASAHI KASEI Corporation), 2 parts by weight of Acryl-based Polymer D1, 0.005 parts by weight of a catalyst (DBTDL) and 3 parts by weight of a curing retarder (acetylacetone) were mixed, a toluene solvent was introduced thereto so that the solid concentration became 48 wt %, and the mixture was stirred using a disper to prepare Adhesive Composition 1.

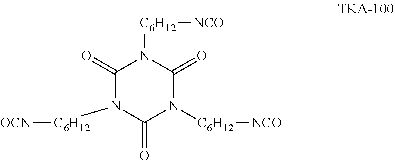

(2) Preparation of Adhesive Composition 2

Adhesive Composition 2 was prepared in the same manner as in Preparation of Adhesive Composition 1 except that Acryl-based Polymer D1 was used in 4 parts by weight with respect to 100 parts by weight of Urethane Polymer U1.

(3) Preparation of Adhesive Composition 3

Adhesive Composition 3 was prepared in the same manner as in Preparation of Adhesive Composition 1 except that Acryl-based Polymer D1 was used in 6 parts by weight with respect to 100 parts by weight of Urethane Polymer U1.

(4) Preparation of Adhesive Composition 4

Adhesive Composition 4 was prepared in the same manner as in Preparation of Adhesive Composition 1 except that Acryl-based Polymer D1 was used in 8 parts by weight with respect to 100 parts by weight of Urethane Polymer U1.

(5) Preparation of Adhesive Composition 5

Adhesive Composition 5 was prepared in the same manner as in Preparation of Adhesive Composition 1 except that Acryl-based Polymer D1 was used in 10 parts by weight with respect to 100 parts by weight of Urethane Polymer U1.

(6) Preparation of Adhesive Composition 6

100 Parts by weight of the prepared Urethane Polymer U2, and, with respect to 100 parts by weight of Urethane Polymer U2, 25 parts by weight of an HDI trimer-based curing agent (TKA-100, ASAHI KASEI Corporation), 10 parts by weight of Acryl-based Polymer D2, 0.005 parts by weight of a catalyst (DBTDL) and 3 parts by weight of a curing retarder (acetylacetone) were mixed, a toluene solvent was introduced thereto so that the solid concentration became 48 wt %, and the mixture was stirred using a disper to prepare Adhesive Composition 6.

(7) Preparation of Adhesive Composition 7

Adhesive Composition 7 was prepared in the same manner as in Preparation of Adhesive Composition 6 except that Acryl-based Polymer D3 was used instead of Acryl-based Polymer D2.

(8) Preparation of Adhesive Composition 8

Adhesive Composition 8 was prepared in the same manner as in Preparation of Adhesive Composition 6 except that Acryl-based Polymer D4 was used instead of Acryl-based Polymer D2.

(9) Preparation of Adhesive Composition 9

Adhesive Composition 9 was prepared in the same manner as in Preparation of Adhesive Composition 6 except that Acryl-based Polymer D5 was used instead of Acryl-based Polymer D2.

(10) Preparation of Adhesive Composition 10 Adhesive Composition 10 was prepared in the same manner as in Preparation of Adhesive Composition 6 except that Acryl-based Polymer D6 was used instead of Acryl-based Polymer D2.

(11) Preparation of Adhesive Composition 11

100 Parts by weight of the prepared Urethane Polymer U1, and, with respect to 100 parts by weight of Urethane Polymer U1, 20 parts by weight of an HDI trimer-based curing agent (TKA-100, ASAHI KASEI Corporation), 7.5 parts by weight of Acryl-based Polymer D7, 0.005 parts by weight of a catalyst (DBTDL) and 3 parts by weight of a curing retarder (acetylacetone) were mixed, a toluene solvent was introduced thereto so that the solid concentration became 48 wt %, and the mixture was stirred using a disper to prepare Adhesive Composition 11.

(12) Preparation of Adhesive Composition 12

Adhesive Composition 12 was prepared in the same manner as in Preparation of Adhesive Composition 11 except that Acryl-based Polymer D8 was used instead of Acryl-based Polymer D7.

(13) Preparation of Adhesive Composition 13

Adhesive Composition 13 was prepared in the same manner as in Preparation of Adhesive Composition 11 except that Acryl-based Polymer D9 was used instead of Acryl-based Polymer D7.

(14) Preparation of Adhesive Composition 14

Adhesive Composition 14 was prepared in the same manner as in Preparation of Adhesive Composition 11 except that Acryl-based Polymer D10 was used instead of Acryl-based Polymer D7.

(15) Preparation of Adhesive Composition 15

Adhesive Composition 15 was prepared in the same manner as in Preparation of Adhesive Composition 11 except that Acryl-based Polymer D11 was used instead of Acryl-based Polymer D7.

(16) Preparation of Adhesive Composition 16

100 Parts by weight of the prepared Urethane Polymer U2, and, with respect to 100 parts by weight of Urethane Polymer U2, 20 parts by weight of an HDI trimer-based curing agent (TKA-100, ASAHI KASEI Corporation), 7.5 parts by weight of Acryl-based Polymer D12, 0.005 parts by weight of a catalyst (DBTDL) and 3 parts by weight of a curing retarder (acetylacetone) were mixed, a toluene solvent was introduced thereto so that the solid concentration became 48 wt %, and the mixture was stirred using a disper to prepare Adhesive Composition 16.

(17) Preparation of Adhesive Composition 17

Adhesive Composition 17 was prepared in the same manner as in Preparation of Adhesive Composition 16 except that Acryl-based Polymer D13 was used instead of Acryl-based Polymer D12.

(18) Preparation of Adhesive Composition 18

Adhesive Composition 18 was prepared in the same manner as in Preparation of Adhesive Composition 16 except that Acryl-based Polymer D14 was used instead of Acryl-based Polymer D12.

(19) Preparation of Adhesive Composition 19

Adhesive Composition 19 was prepared in the same manner as in Preparation of Adhesive Composition 16 except that Acryl-based Polymer D15 was used instead of Acryl-based Polymer D12.

(20) Preparation of Adhesive Composition 20

Adhesive Composition 20 was prepared in the same manner as in Preparation of Adhesive Composition 16 except that Acryl-based Polymer D16 was used instead of Acryl-based Polymer D12.

(21) Preparation of Comparative Composition 1

Comparative Composition 1 was prepared in the same manner as in Preparation of Adhesive Composition 1 except that, instead of Acryl-based Polymer D1, isopropyl myristate (IPMS) was included in 20 parts by weight with respect to 100 parts by weight Urethane Polymer U1.

(22) Preparation of Comparative Composition 2

Comparative Composition 2 was prepared in the same manner as in Preparation of Adhesive Composition 1 except that, instead of Acryl-based Polymer D1, isopropyl myristate (IPMS) was included in 40 parts by weight with respect to 100 parts by weight Urethane Polymer U1.

(23) Preparation of Comparative Composition 3

Comparative Composition 3 was prepared in the same manner as in Preparation of Adhesive Composition 6 except that Acryl-based Polymer D1 was not used.

(24) Preparation of Comparative Composition 4

Comparative Composition 4 was prepared in the same manner as in Preparation of Adhesive Composition 6 except that, instead of Acryl-based Polymer D2, isopropyl myristate (IPMS) was included in 20 parts by weight with respect to 100 parts by weight Urethane Polymer U2.

(25) Preparation of Comparative Composition 5

Comparative Composition 5 was prepared in the same manner as in Preparation of Adhesive Composition 11 except that Acryl-based Polymer D7 was not used.

(26) Preparation of Comparative Composition 6

Comparative Composition 6 was prepared in the same manner as in Preparation of Adhesive Composition 11 except that, instead of Acryl-based Polymer D7, isopropyl myristate (IPMS) was included in 20 parts by weight with respect to 100 parts by weight Urethane Polymer.

(27) Preparation of Comparative Composition 7

Comparative Composition 7 was prepared in the same manner as in Preparation of Adhesive Composition 16 except that Acryl-based Polymer D12 was not used.

(28) Preparation of Comparative Composition 8

Comparative Composition 8 was prepared in the same manner as in Preparation of Adhesive Composition 16 except that, instead of Acryl-based Polymer D12, isopropyl myristate (IPMS) was included in 20 parts by weight with respect to 100 parts by weight Urethane Polymer.

4. Peeling Performance Test

(1) Preparation of Surface Protective Film

A polyethylene terephthalate (PET) film (H330, KOLON) with a thickness of 75 μm having an antistatic layer with a thickness of 50 nm each were coated on both surfaces of a base film was prepared as a base layer. As a protective layer, a film with a thickness of 50 μm (12ASW, SKC Corporation) in which an antistatic layer is formed on both surfaces of a polyethylene terephthalate (PET) film (XD510P, Toray Advanced Materials Korea Inc.) and a release layer is coated on one of the antistatic layers was prepared. Then, the adhesive composition prepared above was comma coated on one surface of the base layer to a thickness of 75 μm, and after hot air drying the result, the protective layer was laminated on the coated adhesive composition so that the base layer and the release layer face each other, and the result was aged for 5 days at 40° C. to prepare a surface protective film.

(2) Measurement of Low temperature Low Rate Peel Strength

The prepared surface protective film was cut to a width of 25 mm and a length of 150 mm. The protective layer was peeled from the cut surface protective film, and the adhesive layer of the surface protective film was attached to glass using a 2 kg roller. The result was stored for 24 hours under a temperature of 25° C. and relative humidity of 50%, and, using a texture analyzer (manufactured by Stable Micro Systems, UK), peel strength when peeling the surface protective film from the glass at a peeling rate of 1.8 m/min and a peeling angle of 180° at 25° C. was measured. The peel strength was measured on the same two specimens, and an average value thereof was employed.

(3) Measurement of High temperature Peel Strength

The prepared surface protective film was cut to a width of 25 mm and a length of 150 mm. The protective layer was peeled from the cut surface protective film, and the adhesive layer of the surface protective film was attached to glass using a 2 kg roller, and the result was stored for 24 hours at 25° C. Using a texture analyzer (manufactured by Stable Micro Systems, UK) equipped with a heating chamber, high temperature peel strength was evaluated while, after leaving the adhesive layer-formed base film unattended for 1 minute at 50° C., peeling the surface protective film from the glass at a peeling rate of 1.8 m/min and a peeling angle of 180° at 50° C. The high temperature peel strength was measured on the same two specimens, and an average value thereof was employed.

(4) Measurement of Adhesive Strength Retention Rate

A ratio of the measured high temperature peel strength with respect to the measured low temperature peel strength {(high temperature peel strength)/(low temperature peel strength)×100(%)} was calculated to obtain an adhesive strength retention rate.

(5) Measurement of High Rate Peel Strength

The prepared surface protective film was cut to a width of 25 mm and a length of 150 mm. The protective layer was peeled from the cut surface protective film, and the adhesive layer of the surface protective film was attached to glass using a 2 kg roller. The result was stored for 24 hours under a temperature of 25° C. and relative humidity of 50%, and, using a texture analyzer (manufactured by Stable Micro Systems, UK), peel strength when peeling the surface protective film from the glass at a peeling rate of 30 m/min and a peeling angle of 180° at 25° C. was measured. The peel strength was measured on the same two specimens, and an average value thereof was employed.

(6) Measurement of Residual Adhesion Rate

The residual adhesion rate means a ratio of an adhesive remaining in the adhesive layer without being left on the adherend when the adhesive layer is adhered to the adherend and then peeled off. The ratio may be calculated as a ratio of adhesive strength (B) of the glass surface gone through adhering and peeling of the adhesive layer with respect to initial adhesive strength (A) of the glass surface without adhering and peeling of the adhesive layer of the present disclosure. The adhesive strength (A) and the adhesive strength (B) are compared by measuring adhesive strength when adhering an adhesive (Ref.) prepared in advance to a glass surface, leaving the result unattended and peeling the adhesive. As the adhesive (Ref.), 9002D of LG Chem., an adhesive having peel strength of 1,800×100 gf/in when, after adhering to a glass surface, peeling at a rate of 1.8 m/min and a peeling angle of 180° was used.

Adhesive strength(B): the adhesive layer of the disclosure of the present application was adhered to a glass surface, left unattended, and adhesive strength of the glass surface from which the adhesive layer was peeled was measured for the adhesive (Ref.).

Adhesive strength(A): adhesive strength of the glass surface without gone through the adhering, the being left unattended and the peeling was measured for the adhesive (Ref.).

Condition of being left unattended: being left unattended consecutively for 24 hours at 25° C., 10 days at 60° C. and relative humidity of 90%, and 24 hours at 25° C.

Specifically, the adhesive strength (A) and the adhesive strength (B) were measured through the following methods.

Measurement of adhesive strength (B): the protective layer was peeled from the cut surface protective film, and the adhesive layer of the surface protective film was attached to glass. The result was stored for 24 hours at 25° C., and then stored for 10 days in a thermo-hydrostat with a temperature of 60° C. and relative humidity of 90%. After that, the film was taken out and left unattended for 24 hours at 25° C., and then the surface protective film was removed from the glass. The adhesive (Ref.) was attached to the surface protective film-removed glass surface, stored for 1 hour in a 40° C. oven and then left unattended for 4 hours at 25° C., and, using a texture analyzer (manufactured by Stable Micro Systems, UK), peel strength when peeling the adhesive (Ref.) from the glass at a peeling rate of 1.8 m/min and a peeling angle of 180° was measured. This was employed as adhesive strength (B).

Measurement of adhesive strength (A): adhesive strength (A) was measured in the same manner as the adhesive strength (B) except that the process of attaching and then peeling the adhesive layer of the surface protective film from the glass was not conducted.

Specifically, the adhesive (Ref.) was attached to glass, stored for 1 hour in a 40° C. oven and then left unattended for 4 hours at 25° C., and, using a texture analyzer (manufactured by Stable Micro Systems, UK), peel strength when peeling the adhesive (Ref.) from the glass at a peeling rate of 1.8 m/min and a peeling angle of 180° was evaluated. This was employed as adhesive strength (A).

A residual adhesion rate was obtained by substituting the adhesive strength (A) and adhesive strength (B) into the following equation.

Residual adhesion rate (%)={adhesive strength (B)}/{adhesive strength(A)}*100

TABLE 1

| | Example | Example | Example | Example | Example | Compar. | Compar. |
|---|---|---|---|---|---|---|---|
| | 1 | 2 | 3 | 4 | 5 | Ex. 1 | Ex. 2 |
| Adhesive Layer | Adh. | Adh. | Adh. | Adh. | Adh. | Compar. | Compar. |
| Composition | Comp. 1 | Comp. 2 | Comp. 3 | Comp. 4 | Comp. 5 | Comp. 1 | Comp. 2 |
| Acryl -Based | 2 | 4 | 6 | 5 | 10 | Not Incl. | Not Incl. |
| Polymer Content | | | | | | | |
| (Parts by Weight) | | | | | | | |
| with Respect to | | | | | | | |
| 100 Parts by | | | | | | | |
| Weight of Urethane | | | | | | | |
| Polymer | | | | | | | |
| BMA/STMA/FM- | 79.5/10/ | 79.5/10/ | 79.5/10/ | 79.5/10/ | 79.5/10/ | — | — |
| 0721/HBA | 0.5/10 | 0.5/10 | 0.5/10 | 0.5/10 | 0.5/10 | | |
| Content Ratio | | | | | | | |
| Low Temperature | 4.8 | 4.2 | 3.5 | 2.8 | 1.4 | 14 | 11 |
| Low Rate Peel | | | | | | | |
| Strength (gf/in) | | | | | | | |
| High Temperature | 2.3 | 2.1 | 1.8 | 1.7 | 0.9 | 4.2 | 3.8 |
| Low Rate Peel | | | | | | | |
| Strength (gf/in) | | | | | | | |
| Adhesive Strength | 48% | 50% | 51% | 60% | 64% | 30% | 34% |
| Retention Rate (%) | | | | | | | |

TABLE 2

| | Example | Example | Example | Example | Example | Compar. | Compar. |
|---|---|---|---|---|---|---|---|
| | 6 | 7 | 8 | 9 | 10 | Ex. 3 | Ex. 4 |
| Adhesive | Adh. | Adh. | Adh. | Adh. | Adh. | Compar. | Compar. |
| Layer | Comp. 6 | Comp. 7 | Comp. 8 | Comp. 9 | Comp. 10 | Comp. 3 | Comp. 4 |
| Composition | | | | | | | |
| Acryl-Based | 10 | 10 | 10 | 10 | 10 | Not | Not |
| Polymer | | | | | | Incl. | Incl. |
| Content | | | | | | | |
| (Parts by | | | | | | | |
| Weight) with | | | | | | | |
| Respect to | | | | | | | |
| 100 Parts by | | | | | | | |
| Weight of | | | | | | | |
| Urethane | | | | | | | |
| Polymer | | | | | | | |
| BMA/STMA/FM- | 79.5/5/ | 82.5/5/ | 84.5/5/ | 86.5/5/ | 88.5/5/ | — | — |
| 0721/HHA | 0.5/15 | 0.5/12 | 0.5/10 | 0.5/8 | 0.5/5 | | |
| Content Ratio | | | | | | | |
| OH value | 48.9 | 39.1 | 32.6 | 26.1 | 16.3 | — | — |
| (mg/KOH) | | | | | | | |
| Low | 1.4 | 1.9 | 2.6 | 3.8 | 4.6 | 14 | 11 |
| Temperature | | | | | | | |
| Low Rate Peel | | | | | | | |
| Strength | | | | | | | |
| (gf/in) | | | | | | | |
| High | 0.9 | 1.2 | 1.4 | 2.2 | 2.2 | 4.2 | 3.8 |
| Temperature | | | | | | | |
| Low Rate Peel | | | | | | | |
| Strength | | | | | | | |
| (gf/in) | | | | | | | |
| Adhesive | 64% | 63% | 53% | 52% | 47% | 30% | 34% |
| Strength | | | | | | | |
| Retention | | | | | | | |
| Rate (%) | | | | | | | |

TABLE 3

| | Example | Example | Example | Example | Example | Compar. | Compar. |
|---|---|---|---|---|---|---|---|
| | 11 | 12 | 13 | 14 | 15 | Ex. 5 | Ex. 6 |
| Adhesive | Adh. | Adh. | Adh. | Adh. | Adh. | Compar. | Compar. |
| Layer | Comp. 11 | Comp. 12 | Comp. 13 | Comp. 14 | Comp. 15 | Comp. 5 | Comp. 6 |
| Composition | | | | | | | |
| Si-acrylate | X-24-8201 | X-24-8201 | FM-0721 | FM-0721 | FM-0721 | Not | Not |
| Type | | | | | | Incl. | Incl. |
| Molecular | 15,000 | 27,000 | 30,000 | 35,000 | 39,000 | — | — |
| Weight of | | | | | | | |
| Acryl-based | | | | | | | |
| Polymer | | | | | | | |
| (g/mol) | | | | | | | |
| Plasticizer | — | — | — | — | — | — | IPMS |
| Type | | | | | | | |
| Low | 1.6 | — | — | — | 1.1 | 14 | 11 |
| Temperature | | | | | | | |
| Low Rate Peel | | | | | | | |
| Strength | | | | | | | |
| (gf/in) | | | | | | | |
| High Rate | 6.5 | 2.7 | 1.5 | 2.5 | 4 | 65 | 52 |
| Peel Strength | | | | | | | |
| (gf/in) | | | | | | | |
| Residual | 89 | — | — | — | 85 | 78 | 68 |
| Adhesion Rate | | | | | | | |
| (%) | | | | | | | |

TABLE 4

| | Example | Example | Example | Example | Example | Compar. | Compar. |
|---|---|---|---|---|---|---|---|
| | 16 | 17 | 18 | 19 | 20 | Ex. 7 | Ex. 8 |
| Adhesive | Adh. | Adh. | Adh. | Adh. | Adh. | Compar. | Compar. |
| Layer | Comp. 16 | Comp. 17 | Comp. 18 | Comp. 19 | Comp. 20 | Comp. 7 | Comp. 8 |
| Composition | | | | | | | |
| Number of | 10 | 12 | 14 | 18 | 22 | — | — |
| Carbon of | | | | | | | |
| Alkyl Group | | | | | | | |
| of Alkyl | | | | | | | |
| (Meth)acrylate | | | | | | | |
| Low | 2.8 | 2.3 | 2 | 1.5 | 1.2 | 14 | 11 |
| Temperature | | | | | | | |
| Low Rate Peel | | | | | | | |
| Strength | | | | | | | |
| (gf/in) | | | | | | | |
| High Rate | 16.7 | 13.5 | 9.8 | 6.5 | 4.9 | 65 | 52 |
| Peel Strength | | | | | | | |
| (gf/in) | | | | | | | |
| Residual | 93 | 83 | 90 | 89 | 86 | 78 | 68 |
| Adhesion Rate | | | | | | | |
| (%) | | | | | | | |

From the experimental results, it was determined that the low temperature low rate peel strength of the adhesive layer was 5 gf/in or less in the surface protective film of the present disclosure, however, the low temperature low rate peel strength of the adhesive layer was greater than 5 gf/in in the surface protective film of the comparative example.

In addition, it was determined that the adhesive strength retention rate (%) of the adhesive layer was greater than 45% in the surface protective film of the present disclosure, however, the adhesive strength retention rate (%) of the adhesive layer was less than 45% in the surface protective film of the comparative example.

In addition, it was determined that the high rate peel strength of the adhesive layer was 10 gf/in or less in the surface protective film of the present disclosure, however, the high rate peel strength of the adhesive layer was far too high in the surface protective film of the comparative example.

In addition, it was determined that the surface protective film of the present disclosure had a high residual adhesion rate of 80% or greater, and the adhesive did not smear much on the adherend.

Accordingly, it was determined that the adhesive layer used in the surface protective film of the present disclosure was effective in that it had proper ranges of low rate peel strength and high rate peel strength, had no decrease in the peel strength even when raising temperature, and had the adhesive not smearing much on the adherend.

1. A surface protective film comprising:
a base layer; and
an adhesive layer provided on one surface of the base layer,
wherein the adhesive layer includes a cured material of an adhesive composition including a urethane polymer; an acryl-based polymer; and a curing agent;
the acryl-based polymer includes a (meth)acrylate monomer including an alkyl group having 10 or more carbon atoms; a (meth)acrylate monomer including a hydroxyl group; and a (meth)acrylate monomer including silicone as a monomer unit; and
a peel strength when peeling a surface opposite to the base layer-provided surface of the adhesive layer from glass at a peeling rate of 1.8 m/min and a peeling angle of 180° is greater than or equal to 0.5 gf/in and less than or equal to 5 gf/in.

2. The surface protective film of claim 1, wherein the adhesive layer has an adhesive strength retention rate of 45% or greater:
the adhesive strength retention rate of the adhesive layer is (high temperature peel strength)/(low temperature peel strength)×100(%);
low temperature peel strength obtained when attaching the adhesive layer of the surface protective film to glass, storing the result for 24 hours at 25° C., and then peeling the surface protective film from the glass at a peeling rate of 1.8 m/min and a peeling angle of 180° at a temperature of 25° C.; and
high temperature peel strength obtained when attaching the adhesive layer of the surface protective film to glass, storing the result for 24 hours at 25° C. and then 1 minute at 50° C., and peeling the surface protective film from the glass at a peeling rate of 1.8 m/min and a peeling angle of 180° at a temperature of 50° C.

3. The surface protective film of claim 1, wherein peel strength when peeling a surface opposite to the base layer-provided surface of the adhesive layer from glass at a peeling rate of 30 m/min and a peeling angle of 180° that is greater than or equal to 1 gf/in and less than or equal to 10 gf/in.

4. The surface protective film of claim 1, wherein a surface opposite to the base layer-provided surface of the adhesive layer has a residual adhesion rate of 80% or greater.

5. The surface protective film of claim 1, wherein the acryl-based polymer is included in 1 parts by weight to 20 parts by weight, with respect to 100 parts by weight of the urethane polymer.

6. The surface protective film of claim 1, wherein the acryl-based polymer has a weight average molecular weight of 10,000 g/mol to 70,000 g/mol.

7. The surface protective film of claim 1, wherein the (meth)acrylate monomer including an alkyl group having 10 or more carbon atoms is included in 5% by weight to 20% by weight, with respect to a total amount of the monomer unit included in the acryl-based polymer.

8. The surface protective film of claim 1, wherein the (meth)acrylate monomer including silicone is included in 0.1% by weight to 5% by weight, with respect to a total amount of the monomer unit included in the acryl-based polymer.

9. The surface protective film of claim 1, wherein the (meth)acrylate monomer including a hydroxyl group is included in 1% by weight to 20% by weight, with respect to a total amount of the monomer unit included in the acryl-based polymer.

10. The surface protective film of claim 1, wherein the urethane polymer has a weight average molecular weight of 60,000 g/mol to 160,000 g/mol.

11. The surface protective film of claim 1, wherein the urethane polymer includes a hydroxyl group.

12. The surface protective film of claim 1, wherein the base layer includes a base film; and a first antistatic layer and a second antistatic layer provided on both surfaces of the base film, and the adhesive layer is provided on a surface of the second antistatic layer opposite to the surface provided to the base layer.

13. The surface protective film of claim 1, further comprising a protective layer provided on a surface of the adhesive layer opposite to the surface provided to the base layer.

14. The surface protective film of claim 13, wherein the protective layer consecutively includes a release layer; a third antistatic layer; a protective film; and a fourth antistatic layer, and the adhesive layer is provided on a surface of the release layer opposite to the surface presented to the third release layer.

15. An adhesive composition comprising:
a urethane polymer;
an acryl-based polymer; and
a curing agent,
wherein the acryl-based polymer includes a (meth)acrylate monomer including an alkyl group having 10 or more carbon atoms; a (meth)acrylate monomer including a hydroxyl group; and a (meth)acrylate monomer including silicone as a monomer unit.

16. A method for preparing the surface protective film of claim 1, the method comprising:
coating the adhesive composition on one surface of the base layer; and
curing the coated adhesive composition,
wherein the adhesive composition includes a urethane polymer; an acryl-based polymer; and a curing agent; and
the acryl-based polymer includes a (meth)acrylate monomer including an alkyl group having 10 or more carbon atoms; a (meth)acrylate monomer including a hydroxyl group; and a (meth)acrylate monomer including silicone as a monomer unit.

17. A method for manufacturing an organic light emitting electronic device, the method comprising attaching the adhesive layer of the surface protective film of claim 1 on an encapsulation layer of an organic light emitting device.

18. The method for manufacturing an organic light emitting electronic device of claim 17, wherein the organic light emitting device consecutively includes glass, a plastic substrate, a thin film transistor, an organic light emitting diode and an encapsulation layer.

19. The method for manufacturing an organic light emitting electronic device of claim 17, further comprising:
peeling off the surface protective film from the encapsulation layer; and
laminating a touch screen panel and a cover window on the encapsulation layer.
